(19) United States
(12) Patent Application Publication
(10) Pub. No.: US 2005/0275099 A1
(43) Pub. Date: Dec. 15, 2005

(54) Semiconductor apparatus and method of manufacturing semiconductor apparatus

(76) Inventor: Daijiro Takano, Komatsu-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/139,558

(22) Filed: May 31, 2005

(30) Foreign Application Priority Data
Jun. 9, 2004 (JP) 2004-171533

(51) Int. Cl. H01L 23/48; H01L 21/48

(52) U.S. Cl. 257/738; 257/778; 257/786; 438/108

(57) ABSTRACT

A semiconductor apparatus comprises a circuit board on which a plurality of wiring patterns are formed, a semiconductor device having a plurality of bumps electrically connected to the wiring patterns, the semiconductor device being mounted onto the circuit board via the bumps, the wiring patterns including a pair of wiring patterns for measuring connection resistance, and the pair of wiring patterns having tip portions which are arranged with a gap therebetween and connected to one of the bumps.

### CROSS-REFERENCE TO RELATED APPLICATIONS

This application is based upon and claims the benefit of priority from prior Japanese Patent Application No. 2004-171533, filed Jun. 9, 2004, the entire contents of which are incorporated herein by reference.

### BACKGROUND OF THE INVENTION

1. Field of the Invention

The present invention relates to a semiconductor apparatus in which a semiconductor device having bumps for electric connection has been mounted, and in particular, to a semiconductor apparatus having a structure in which a value of resistance of a bump connected via an anisotropic conductive film and a wiring pattern of a circuit board can be easily measured after mounting, and a method of manufacturing the semiconductor apparatus.

2. Description of the Related Art

Accompanying the high-functionalizing and the multi-functionalizing of equipment having a semiconductor device mounted therein, there is a trend that the high-integrating and the large-scaling of a semiconductor device further make progress, and the number of electric connecting portions which connect a semiconductor device and a circuit board is increased. As a form for mounting a semiconductor device onto a circuit board, a form in which a semiconductor device having bumps for electric connection formed thereon is directly mounted onto a circuit board has been going to be broadly used. Such a structure of mounting a semiconductor device is effective in a reduction of a mounting area, and is suitable for the miniaturization of a semiconductor apparatus.

In this way, in a structure in which a semiconductor device is directly mounted onto a circuit board via bumps for electric connection, the reliability of connection between gold bumps by an anisotropic conductive film and a panel electrode of the circuit board is extremely important. Further, it is necessary to inspect whether or not an electric connection is carried out in a predetermined state after mounting. Therefore, as disclosed in, for example, Jpn. Pat. Appln. KOKAI Publication No. 10-93297, a connection state can be judged by measuring a value of connection resistance.

As a semiconductor device to be mounted, for example, a large scale integrated circuit (LSI) can be sampled. The LSI has first to fourth measuring bumps, and first and second LSI internal wirings. The first measuring bump and the second measuring bump are connected by the first LSI internal wiring. The third measuring bump and the fourth measuring bump are connected by the second LSI internal wiring. Further, a circuit board has first to third measuring wiring patterns. When the LSI is mounted onto the circuit board, the first measuring bump is connected to the first measuring wiring pattern, the second and third measuring bumps are connected to the second measuring wiring pattern, and the fourth measuring bump is connected to the third measuring wiring pattern, respectively, via conductive particles.

When an electric current is made to flow between the first measuring wiring pattern and the third measuring wiring pattern in this mounting state, the electric current flows through the route of the first measuring wiring pattern→conductive particles→the first measuring bump→the first LSI internal wiring→the second measuring bump→conductive particles→the second measuring wiring pattern→conductive particles →the third measuring bump→the second LSI internal wiring→the fourth measuring bump→conductive particles→the third measuring wiring pattern. Accordingly, the electric current passes through four points which are connection points by conductive particles at each of the first to fourth measuring bumps. Therefore, the entire connection resistance is measured, and the connection state can be judged by using a quarter of the value as connection resistance at one measuring bump.

In the above-described conventional method of manufacturing a semiconductor apparatus, it is necessary to short circuit between the measuring bumps in the LSI in order to measure connection resistance due to an anisotropic conductive film. Therefore, the manufacturing method can be applied to only customized products made to be suitable for it, and cannot be applied to general purpose LSIs.

### BRIEF SUMMARY OF THE INVENTION

The present invention has been achieved in consideration of the above-described problems, and an object of the present invention is to provide a semiconductor apparatus in which a value of connection resistance due to an anisotropic conductive film can be easily measured after mounting a semiconductor device onto a circuit board, without requesting the semiconductor device a special configuration.

Further, another object of the present invention is to provide a method of manufacturing a semiconductor apparatus in which a value of connection resistance due to an anisotropic conductive film can be easily measured after mounting a semiconductor device onto a circuit board, without requesting the semiconductor device a special configuration.

According to one aspect of the present invention, there is provide to a semiconductor apparatus comprising:

a circuit board on which a plurality of wiring patterns are formed;

a semiconductor device having a plurality of bumps electrically connected to the wiring patterns, the semiconductor device being mounted onto the circuit board via the bumps;

the wiring patterns including a pair of wiring patterns for measuring connection resistance; and

the pair of wiring patterns having tip portions which are arranged with a gap therebetween and connected to one of the bumps.

According to another aspect of the present invention is a method of manufacturing a semiconductor apparatus comprising: a circuit board on which a plurality of wiring patterns are formed; and a semiconductor device having a plurality of bumps electrically connected to the wiring patterns, the semiconductor device being mounted onto the circuit board via the bumps, the method comprising:

disposing on the circuit board a pair of wiring patterns for measuring connection resistance of the wiring patterns, and arranging tip portions of the pair of wiring patterns with a gap therebetween;

mounting the semiconductor device onto the circuit board, and placing one of the bumps on to the tip portions of the pair of wiring patterns; and

making an electric current flow to the pair of wiring patterns, and measuring a value of connection resistance between the pair of wiring patterns.

According to the aspect of the invention, the wiring patterns on the circuit board are merely connected so as to be in a specific state with respect to the bumps for electric connection formed at the semiconductor device in a normal state, and thus, a value of connection resistance due to an anisotropic conductive film can be easily measured by applying the present invention to a general purpose LSI as well.

Additional advantages of the invention will be set forth in the description which follows, and in part will be obvious from the description, or may be learned by practice of the invention. The advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a plan view schematically showing a main portion of a semiconductor apparatus according to an embodiment of the present invention;

FIG. 2 is a sectional view taken along line II-II in FIG. 1;

FIG. 3 is a plan view showing a wiring pattern of a circuit board to which a pair of wiring patterns shown in FIGS. 1 and 2 have been applied;

FIG. 4 is a plan view showing a bump array of a semiconductor device which is mounted onto the circuit board shown in FIG. 3;

FIG. 5 is a front view schematically showing an example of a semiconductor apparatus having a mounting structure via bumps for electric connection;

FIG. 6 is a plan view showing the layout of the bumps of the semiconductor device shown in FIG. 5;

FIG. 7 is a plan view schematically showing a process of mounting an LSI onto a liquid crystal panel;

FIG. 8 is a sectional view taken along line VIII-VIII in FIG. 7;

FIG. 9 is a plan view schematically showing a process, which follows FIG. 7, of mounting the LSI onto the liquid crystal panel;

FIG. 10 is a sectional view taken along line X-X in FIG. 9;

FIG. 11 is a plan view schematically showing a process, which follows FIG. 9, of mounting the LSI onto the liquid crystal panel;

FIG. 12 is a sectional view taken along line XII-XII in FIG. 11;

FIG. 13 is a sectional view in which the process shown in FIGS. 11 and 12 is shown more in detail;

FIG. 14 is a sectional view showing the main portion of FIG. 13 so as to be enlarged, in a state before the LSI is crimped on the liquid crystal panel; and

FIG. 15 is a sectional view showing the main portion of FIG. 13 so as to be enlarged, in a state after the LSI has been crimped on the liquid crystal panel.

### DETAILED DESCRIPTION OF THE INVENTION

Hereinafter, a semiconductor apparatus and a method of manufacturing the semiconductor apparatus according to an embodiment of the present invention will be described in detail with reference to the drawings.

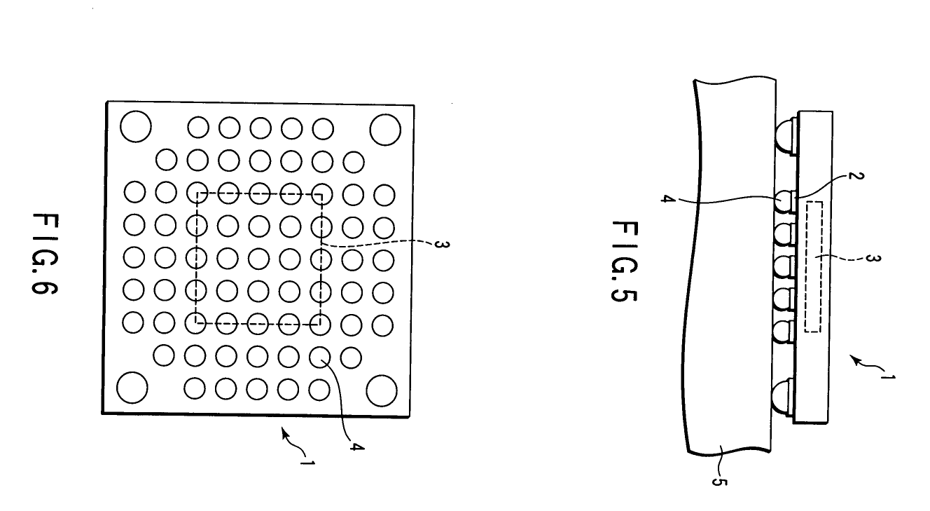

First, an example of a semiconductor apparatus having a mounting structure via bumps 4 for electric connection will be described. As shown in FIGS. 5 and 6, a semiconductor device 1 has a plurality of external electrodes 2 formed in a lattice form on one surface thereof, and these external electrodes 2 and an internal circuit 3 are electrically connected. The bumps 4 are respectively provided to the external electrodes 2. A plurality of wiring patterns (not shown) formed on a circuit board 5 on which the semiconductor device 1 is mounted, and the bumps 4 are connected to one another.

Next, a manufacturing process for electrically connecting the wiring patterns and bumps 4 will be described with reference to FIGS. 7 to 12.

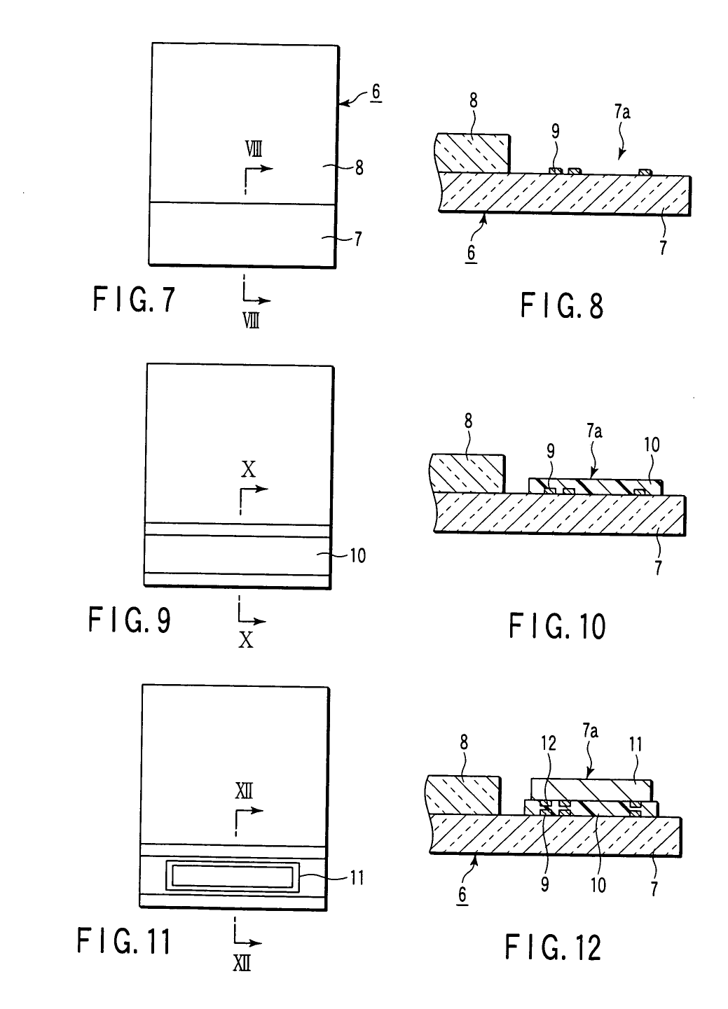

FIGS. 7 to 12 show one example of a case in which an LSI serving as the semiconductor device 1 is mounted onto a liquid crystal panel 6 serving as a circuit board in a process of manufacturing a semiconductor apparatus. As shown in FIGS. 7 and 8, the liquid crystal panel 6 has an array substrate 7 having pixel electrodes and the like formed thereon, and a color filter substrate 8 having a color filter formed thereon. The array substrate 7 has an LSI mounting portion 7a exposed from the color filter substrate 8. A predetermined wiring pattern including panel electrodes 9 is formed onto the LSI mounting portion 7a. An anisotropic conductive film 10 is provided to the LSI mounting portion 7a as shown in FIGS. 9 and 10. Next, as shown in FIGS. 11 and 12, the LSI 11 is mounted on the anisotropic conductive film 10 so as to make the plane on which gold bumps 12 are provided face downward. At that time, due to the panel electrodes 9 at the LSI mounting portion 7a and the gold bumps 12 being face one another, the panel electrodes 9 and the gold bumps 12 are electrically connected to one another by the anisotropic conductive film 10. Therefore, as the panel electrodes 9 and the gold bumps 12 are electrically connected to one another, the bumps 4 shown in FIG. 5 and wiring patterns (not shown) can be electrically connected.

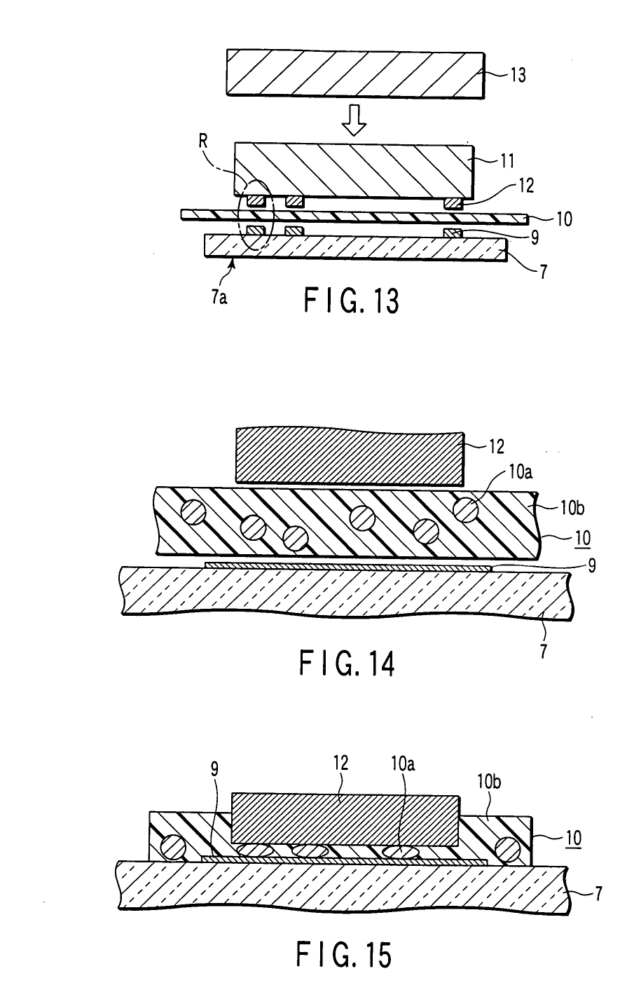

Next, a manufacturing process in which a connection is carried out by the anisotropic conductive film 10 shown in FIGS. 11 and 12 will be described more in detail with reference to FIGS. 13 to 15. FIG. 13 shows a state in which the panel electrodes 9 at the LSI mounting portion 7a and the gold bumps 12 of the LSI 11 are made to face one another via the anisotropic conductive film 10. In this state, a resin of the anisotropic conductive film 10 is hardened while pressing the LSI 11 toward the array substrate 7 by a crimp tool 13. In FIGS. 14 and 15, the vicinity of one bold bump 12 in the process (a region R shown in FIG. 13) is shown to be enlarged.

FIG. 14 shows a state before crimping the LSI 11, and FIG. 15 shows a state after crimping the LSI 11. The anisotropic conductive film 10 has a structure in which conductive particles 10a whose diameters are 3 to 5 μm are dispersed in a resin 10b. As shown in FIG. 14, the gold bump 12 is made to face the panel electrode 9 with the anisotropic conductive film 10 interposed therebetween, and is heated and pressed, whereby a crimping state shown in FIG. 15 is obtained. In this state, the conductive particles 10a are held so as to be flattened between the gold bump 12 and the panel electrode 9. Then, this state is fixed due to the resin 10b being hardened. Since the flattened conductive particles 10a are held between the gold panel 12 and the panel electrode 9, only the conductivity in the direction between the gold panel 12 and the panel electrode 9 can be obtained.

Next, a semiconductor apparatus and a method of manufacturing the semiconductor apparatus according to the embodiment of the present invention will be described in detail. In the semiconductor apparatus according to the embodiment, tip portions of a pair of wiring patterns for measuring connection resistance are preferably set such that areas facing the corresponding gold bump 12 are made equal to one another.

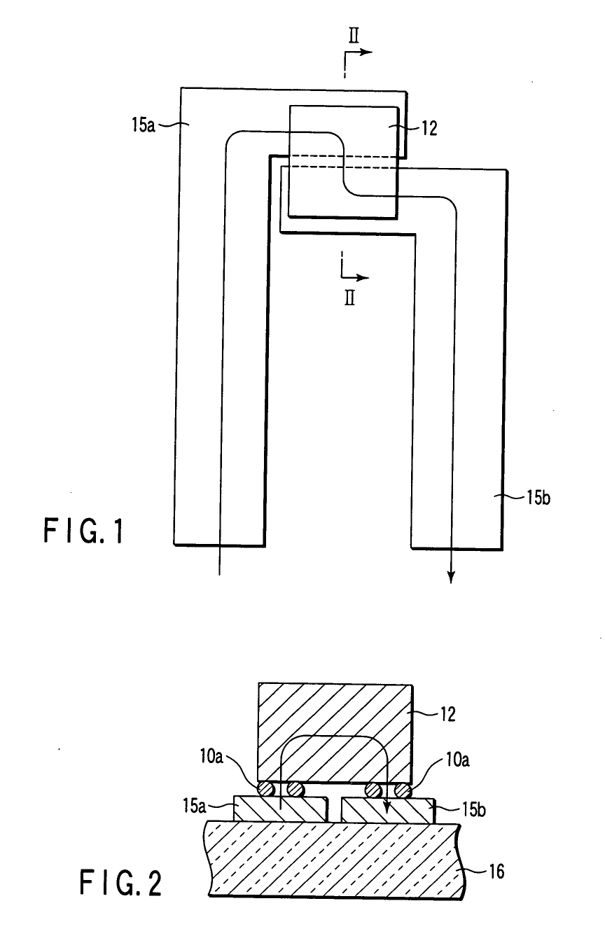

As shown in FIGS. 1 and 2, the gold bump 12 serving as a bump is formed for normal electric connection onto a plane of a semiconductor device such as an LSI in the same way as that shown in FIGS. 12 and 13. Here, in FIGS. 1 and 2, the illustration of the semiconductor device is omitted in consideration of the ease of seeing the drawing. A pair of wiring patterns 15a and 15b for measuring connection resistance are formed on a circuit board 16 such as the array substrate 7 shown in FIGS. 7 to 13.

The pair of wiring patterns 15a and 15b and the gold bump 12 are connected via conductive particles 10a in an anisotropic conductive film (not shown) interposed therebetween. The gold bump 12 is preferably a same size as other connection bumps. The pair of wiring patterns 15a and 15b are disposed so as to correspond to one gold bump 12. The pair of wiring patterns 15a and 15b have tip portions arranged with a gap therebetween. The gap between the tip portions of the pair of wiring patterns 15a and 15b is within a range of the dimension of one gold bump 12. Namely, the gap is provided so as to be able to maintain the overlap between the tip portions of the pair of wiring patterns 15a and 15b and the gold bump 12. The tip portions of the pair of wiring patterns 15a and 15b are respectively connected to some regions of one gold bump 12 so as to provide an anisotropic conductive film therebetween. In the present embodiment, the pair of wiring patterns 15a and 15b and the one gold bump 12 are connected by the conductive particles 10a in the anisotropic conductive film interposed therebetween. However, it is not limited thereto, and a pair of wiring patterns and one gold bump 12 may be electrically connected to one another using electric conductor such as solder.

When an electric current is made to flow between the pair of wiring patterns 15a and 15b in this mounting state, the electric current flows through the route of the wiring pattern 15a→the conductive particles 10a→the gold bump 12→the conductive particles 10a→the wiring pattern 15b. Accordingly, the electric current passes through two points serving as connection points by the conductive particles 10a. However, the total of projected contact areas of the two points corresponds to the projected contact area of one gold bump 12. Therefore, if a value of connection resistance of the entire device is measured in the manufacturing process, the connecting state due to the one gold bump 12 can be judged.

In accordance with the semiconductor apparatus configured as described above and the method of manufacturing the semiconductor apparatus, a special configuration for measuring connection resistance is not required of the semiconductor device with respect to the formation of the gold bump 12. Namely, a normal semiconductor device such as a general purpose LSI is used as is, and the wiring patterns at the side of the circuit board 16 may be made in a special form and a special layout for measurement. Consequently, after mounting the semiconductor device onto the circuit board 16, a value of connection resistance due to an anisotropic conductive film can be easily measured. Further, because it is sufficient to have a short route for making an electric current flow in order to measure a value of resistance, the precision in the measured results is sufficiently high.

The pair of wiring patterns 15a and 15b are preferably formed such that the areas respectively facing the corresponding gold bump 12 are equal to each other. In order to execute the measuring connection resistance according to the embodiment, it is recommended that the dimension of the gold bump 12 is, for example, 80 μm×80 μm. The material of the gold bumps 12 is gold. In place of the gold bumps 12, bumps made of another conductive material may be used. The configuration of the present embodiment can be applied to the circuit board 16 made of epoxy resin, or even in a case of a glass substrate as in a case of the liquid crystal display described above as well. The configuration of the embodiment can be applied to a semiconductor device formed so as to be a resin or ceramic package, or so as to be a bare chip as well.

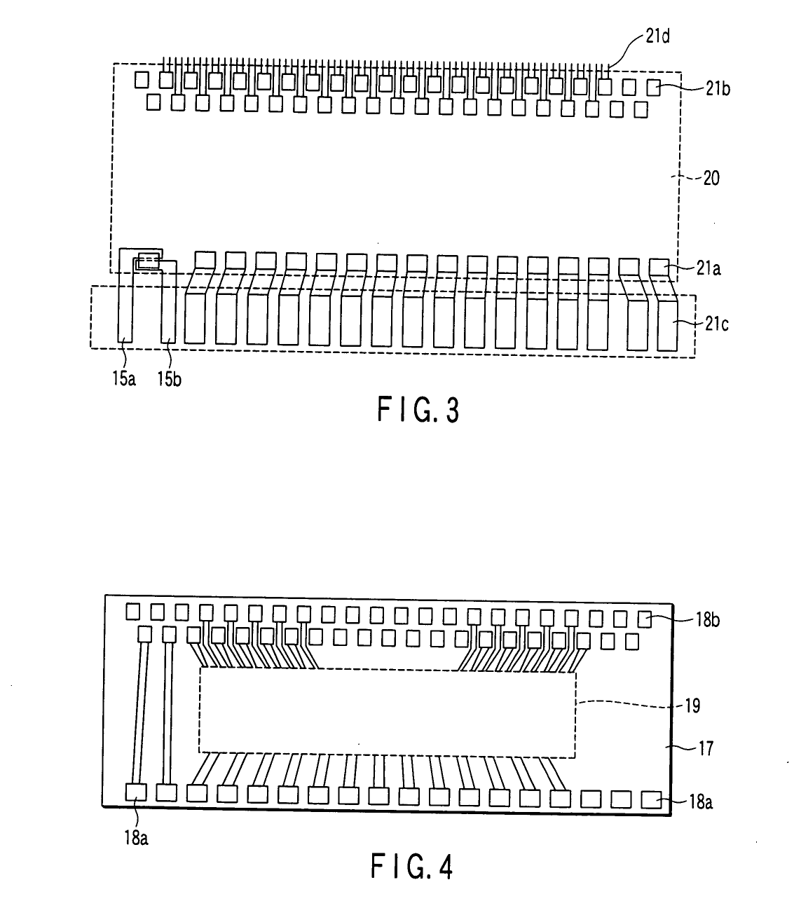

FIG. 3 shows one example of wiring patterns on a circuit board 20. FIG. 4 shows one example of a bump array on a semiconductor device 17.

As shown in FIG. 4, a plurality of input bumps 18a and a plurality of output bumps 18b are formed on the bottom plane of the semiconductor device 17. Some of the input bumps 18a and the output bumps 18b are connected to an internal circuit 19, and further, some of those are connected to one another. Here, FIG. 4 is drawn in a state in which the input bumps 18a and the output bumps 18b formed on the bottom plane are seen through from the side of the top plane in order to easily understand the relationship of the circuit board 20 with the wiring patterns shown in FIG. 3.

As shown in FIG. 3, a plurality of wiring patterns including a plurality of input pads 21a, a plurality of output pads 21b, and a plurality of FOG pads 21c are disposed on the circuit board 20. Some of the output pads 21b are connected to other regions of the circuit board 20 by wirings 21d. Moreover, a pair of wiring patterns 15a and 15b for measuring connection resistance are formed in place of the input pad 21a and the FOG pad 21a at one place on the circuit board 20. Note that the pair of wiring patterns 15a and 15b are the same as those shown in FIG. 1.

As shown in FIGS. 3 and 4, the input pads 21a and the output pads 21b are respectively connected to the input bumps 18a and the output bumps 18b of the semiconductor device 17 via an anisotropic conductive film.

The tip portions of the pair of wiring patterns 15a and 15b are connected to one of the input bumps 18a of the semiconductor device 17 as described above. Consequently, a connection for measuring connection resistance is carried out.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A semiconductor apparatus comprising:
a circuit board on which a plurality of wiring patterns are formed;
a semiconductor device having a plurality of bumps electrically connected to the wiring patterns, the semiconductor device being mounted onto the circuit board via the bumps;
the wiring patterns including a pair of wiring patterns for measuring connection resistance; and
the pair of wiring patterns having tip portions which are arranged with a gap therebetween and connected to one of the bumps.

2. The semiconductor apparatus according to claim 1, wherein the tip portions of the pair of wiring patterns are formed such that areas thereof facing the one of the bumps are equal to each other.

3. The semiconductor apparatus according to claim 1, further comprising an anisotropic conductive film which is provided between the tip portions of the pair of wiring patterns and the one of the bumps, and which connects the tip portions of the pair of wiring patterns and the one of the bumps.

4. The semiconductor apparatus according to claim 1, wherein the gap between the tip portions of the pair of wiring patterns is within a range of a dimension of the one of the bumps.

5. A method of manufacturing a semiconductor apparatus comprising: a circuit board on which a plurality of wiring patterns are formed; and a semiconductor device having a plurality of bumps electrically connected to the wiring patterns, the semiconductor device being mounted onto the circuit board via the bumps, the method comprising:
disposing on the circuit board a pair of wiring patterns for measuring connection resistance of the wiring patterns, and arranging tip portions of the pair of wiring patterns with a gap therebetween;
mounting the semiconductor device onto the circuit board, and placing one of the bumps on to the tip portions of the pair of wiring patterns; and
making an electric current flow to the pair of wiring patterns, and measuring a value of connection resistance between the pair of wiring patterns.

6. The method of manufacturing a semiconductor apparatus, according to claim 5, wherein
the tip portions of the pair of wiring patterns are formed such that areas thereof facing the one of the bumps are equal to each other.

7. The method of manufacturing a semiconductor apparatus, according to claim 5, further comprising:
when the tip portions of the pair of wiring patterns are connected to the one of the bumps,
providing an anisotropic conductive film between the tip portions of the pair of wiring patterns and the one of the bumps; and
connecting the tip portions of the pair of wiring patterns and the one of the bumps by using the anisotropic conductive film.

8. The method of manufacturing a semiconductor apparatus, according to claim 5, wherein
the pair of wiring patterns are disposed within a range of a dimension of the one of the bumps.
